(19) United States
(12) Patent Application Publication
(10) Pub. No.: US 2025/0385683 A1
(43) Pub. Date: Dec. 18, 2025

(54) SIGNAL PROCESSING SYSTEMS WITH MITIGATION OF INTERFERENCE BETWEEN ALIKE CALIBRATIONS

(71) Applicant: Analog Devices International Unlimited Company, Co. Limerick (IE)

(72) Inventors: Nicholas S. Zakas, Londonderry, NH (US); Cristian Enrique Alvarez Fontecilla, Santiago (CL); Huseyin Dinc, Chapel Hill, NC (US); Snehal Prabhu, Apex, NC (US)

(21) Appl. No.: 19/222,697

(22) Filed: May 29, 2025

Related U.S. Application Data
(60) Provisional application No. 63/659,459, filed on Jun. 13, 2024.

(51) Int. Cl. H03M 1/10

(52) U.S. Cl. CPC H03M 1/1014

(57) ABSTRACT

Signal processing systems with mitigation of interference of between alike calibrations are disclosed. In certain embodiments, a signal processing system includes a shared signal processing channel that processes an input signal to generate an output signal, and two or more signal processing slices that each process the output signal from the shared signal processing channel. The shared signal processing channel has an error of a first type, and the signal processing slices each have an error of the first type. The signal processing system further includes a calibration system that provides the signal processing slices with slice correction coefficients that compensate the signal processing slices for the slice errors. The calibration system adjusts each of the slice correction coefficients based on an estimate of the error of the shared signal processing channel.

### CROSS-REFERENCE TO RELATED APPLICATIONS

This application claims the benefit of priority under 35 U.S.C. § 119 of U.S. Provisional Patent Application No. 63/659,459, filed Jun. 13, 2024 and titled “SIGNAL PROCESSING SYSTEMS WITH MITIGATION OF INTERFERENCE BETWEEN ALIKE CALIBRATIONS,” each of which is herein incorporated by reference in its entirety.

### FIELD OF THE DISCLOSURE

Embodiments of the invention relate to electronic systems, and more particularly to, calibration of signal processing systems.

### BACKGROUND

Signal processing systems can suffer from various errors or impairments that can impact the performance of the signal processing system. For example, impairments such as offsets, gain errors, nonlinearities, memory effects, and/or capacitor mismatches are ubiquitous in high-speed, high-resolution analog-to digital converters (ADCs).

### SUMMARY OF THE DISCLOSURE

In one aspect, a signal processing system with mitigation of interference between alike calibrations is disclosed. The signal processing system includes a shared signal processing channel configured to process an input signal to generate an output signal, the shared signal processing channel having a first error of a first type. The signal processing system further includes a plurality of signal processing slices each configured to process the output signal from the shared signal processing channel, the plurality of signal processing slices having a plurality of errors of the first type. The signal processing system further includes a calibration system configured to provide the plurality of signal processing slices with a plurality of slice correction coefficients that compensate the plurality of signal processing slices for the plurality of errors. The calibration system adjusts each of the plurality of slice correction coefficients based on an estimate of the first error.

In another aspect, a method of calibrating a signal processing system is disclosed. The method includes processing an input signal to generate an output signal using a shared signal processing channel that has a first error of a first type, processing the output signal from the shared signal processing channel using a plurality of signal processing slices that have a plurality of errors of the first type, compensating the plurality of signal processing slices for the plurality of errors by providing the plurality of signal processing slices with a plurality of slice correction coefficients from a calibration system, and adjusting each of the plurality of slice correction coefficients based on an estimate of the first error using the calibration system

### BRIEF DESCRIPTION OF THE DRAWINGS

FIG. 1A is a schematic diagram of one example of a signal processing system with calibration.

FIG. 1B is a schematic diagram of one example of a calibration system for the signal processing system of FIG. 1A.

FIG. 2A is a schematic diagram of one embodiment of a calibration system with mitigation of interference between alike calibrations.

FIG. 2B is a schematic diagram of another embodiment of a calibration system with mitigation of interference between alike calibrations.

FIG. 3A is a schematic diagram of one example of a data converter system.

FIG. 3B is a schematic diagram of one example of a calibration system for the data converter system of FIG. 3A.

FIG. 4 is a schematic diagram of one embodiment of a calibration system for the data converter system of FIG. 3A.

### DETAILED DESCRIPTION

The following detailed description of embodiments presents various descriptions of specific embodiments of the invention. However, the invention can be embodied in a multitude of different ways. In this description, reference is made to the drawings where like reference numerals may indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Circuit and layout design techniques for a signal processing system can help reduce impairments. Additionally, the signal processing system can include a calibration system (for instance, running digital-intensive calibration algorithms) to measure and compensate for impairments in the analog and/or digital domains.

Although calibration techniques provide a myriad of benefits (for instance, lower power, smaller area, and/or simplified analog circuit design), calibration also introduces additional complexity at the system level.

For example, an ADC can include multiple calibrations that target an impairment of the same type (e.g., an offset) originating from different locations along the signal path. In such instances, the estimation engines for the calibrations can be biased or corrupted by like-impairments that are supposed to be detected and corrected for elsewhere.

Since the calibrations correct for impairments in the reverse order that they are introduced in the signal path, an impairment that is corrected inaccurately can corrupt the estimation processes of multiple other calibrations downstream. This in turn degrades overall performance of the signal processing system.

Signal processing systems with mitigation of interference of between alike calibrations are disclosed. In certain embodiments, a signal processing system includes a shared signal processing channel that processes an input signal to generate an output signal, and two or more signal processing slices that each process the output signal from the shared signal processing channel. The shared signal processing channel has an error of a first type, and the signal processing slices each have an error of the first type. The signal processing system further includes a calibration system that provides the signal processing slices with slice correction coefficients that compensate the signal processing slices for the slice errors. The calibration system adjusts each of the slice correction coefficients based on an estimate of the error of the shared signal processing channel.

By implementing the signal processing system in this manner, estimates of the errors of the signal processing slices are not contaminated by the error of the shared signal processing channel. This in turn prevents downstream generation of a spurious component that can introduce undesirable artifacts in the signal processing system's output.

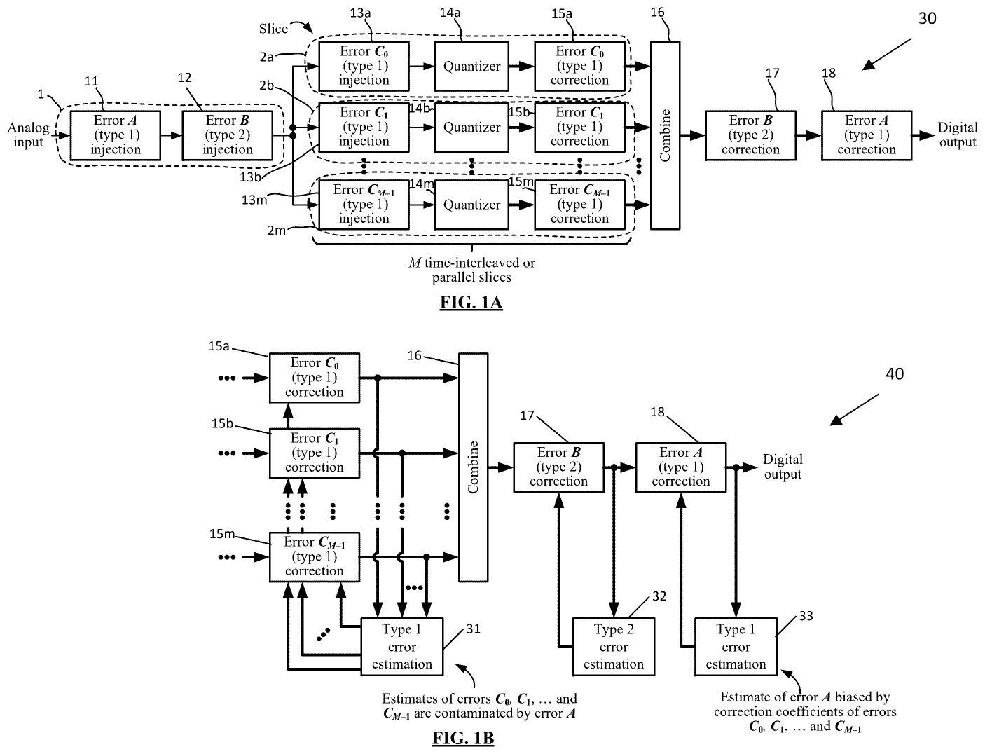

FIG. 1A is a schematic diagram of one example of a signal processing system 30 with calibration. The signal processing system 30 includes a shared signal processing channel 1 that processes an analog input signal to generate an analog output signal. The shared signal processing channel 1 suffers from an error A of a first type (also referred to herein as A error) and an error B of a second type (also referred to herein as B error). The signal processing system 30 further includes M signal processing slices 2a, 2b, . . . 2m that process the analog output signal from the shared signal processing channel 1. M can be any number of two or more slices.

Each of the M signal processing slices 2a, 2b, . . . 2m suffer from an error of the first type. For example, as shown in FIG. 1A, the M signal processing slices 2a, 2b, . . . 2m suffer from errors C₀, C₁, . . . C_{M-1}, respectively.

In the illustrated embodiment, the M signal processing slices 2a, 2b, . . . 2m include quantizers 141a, 14b, . . . 14m, respectively, that provide analog-to-digital conversion of the analog slice output signals of each of the M signal processing slices 2a, 2b, . . . 2m.

The signal processing system 30 also includes calibration that corrects for the errors in a reverse order relative to the point they were introduced along the signal path. Thus, the error correction components 15a, 15b, . . . 15m initially correct for the errors C₀, C₁, . . . C_{M-1} of the M signal processing slices 2a, 2b, . . . 2m. Thereafter, a combiner 16 combines the corrected slice output signals. Additionally, the error correction component 17 corrects the combined output signal from the combiner 16 to correct for the B error of the shared signal processing channel 1, and thereafter the error correction component 18 corrects for the A error of the shared signal processing channel 1 to generate a digital output signal of the signal processing system 30.

The signal processing system 30 of FIG. 1A represents a high-level diagram of an example system where an analog signal is subject to three different circuit blocks that inject errors before being digitized by M slices. Although an example with three errors is shown, the signal processing systems herein can include more or fewer errors.

The signal processing system 30 of FIG. 1A can represent, for example, a time-interleaved ADC where an input amplifier drives M nominally identical sub-ADCs (slices). In such an example, the input amplifier introduces two errors A and B, whereas the slices introduce errors Cᵢ, for i=0, 1, . . . , M−1. After digitization the Cᵢ errors are corrected for on a per slice basis, followed by the B error correction, followed by the A error correction.

FIG. 1B is a schematic diagram of one example of a calibration system 40 for the signal processing system 30 of FIG. 1A. The calibration system 40 includes error correction components 15a, 15b, . . . 15m for correcting for the errors C₀, C₁, . . . C_{M-1} of the M signal processing slices 2a, 2b, . . . 2m. Additionally, the calibration system 40 further includes a combiner 16 for combing the outputs of the error correction components 15a, 15b, . . . 15m, an error correction component 17 for correcting the output of the combiner 16 for the B error of the shared signal processing channel 1, and an error correction component 18 for correcting the output of the error correction component 17 for the A error of the shared signal processing channel 1.

In the illustrated embodiment, the calibration system 40 further includes a first type 1 error estimation block 31 for estimating the errors C₀, C₁, . . . C_{M-1} of the M signal processing slices 2a, 2b, . . . 2m and for generating slice correction coefficients for correcting for the Cᵢ errors. The calibration system 40 further includes a type 2 error estimation block 32 for estimating the error B of the shared signal processing channel 1 and for generating a correction coefficient for correcting the B error. The calibration system 40 further includes a second type 1 error estimation block 33 for estimating the error A of the shared signal processing channel 1 and for generating a correction coefficient for correcting the A error.

As shown in FIG. 1B, the three impairments are addressed in a feedback fashion. Each estimation block or engine 31-33 monitors the residual error right after the correction has been performed, and the correction coefficients are adjusted to minimize the sensed residual error.

Although one example of calibration is shown, other implementations are possible. For example, one or more impairments can be addressed in a feedforward fashion where the error measurement takes place prior to the correction and/or one or more of the estimation blocks can tap other nodes in the system. Furthermore, although the calibration of FIG. 1B depicts an example in which all corrections take place in the digital domain, one or more of the corrections can take place in the analog domain.

As shown in FIGS. 1A and 1B, error A and errors C₀, C₁, . . . C_{M-1} are of the same type (labeled as type 1), whereas error B is of a different type (labeled as type 2). The estimation engines associated with error A and errors C₀, C₁, . . . C_{M-1} often operate based at least in part on a common principle, which can cause the estimates of the errors C₀, C₁, . . . C_{M-1} to be biased by the presence of error A, and for the estimate of error A to be biased by the correction coefficients associated with the errors C₀, C₁, . . . C_{M-1}. This, in turn, can cause the correction block associated with error B to have a spurious component of error A at its input, which can introduce undesirable artifacts at the signal processing system's output.

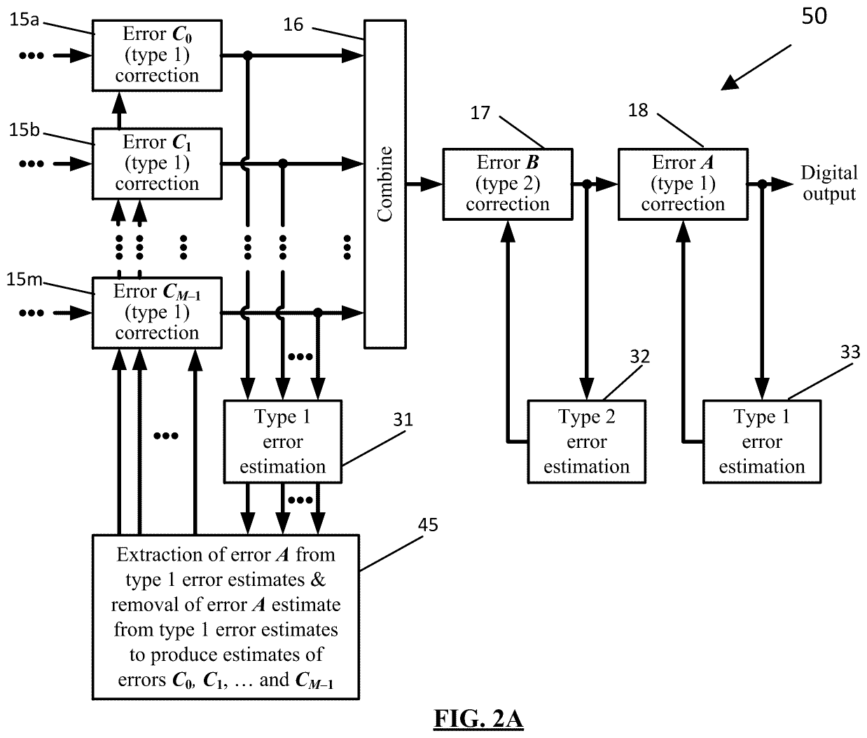

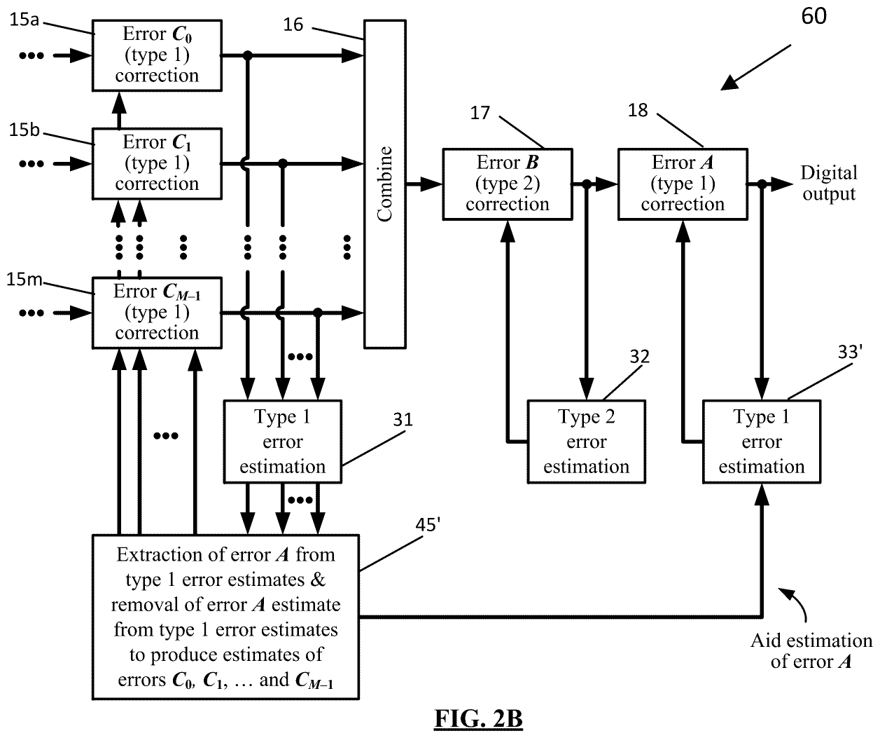

FIG. 2A is a schematic diagram of one embodiment of a calibration system 50 with mitigation of interference between alike calibrations. The calibration system 50 includes error correction components 15a, 15b, . . . 15m for correcting for the errors C₀, C₁, . . . C_{M-1} of M signal processing slices 2a, 2b, . . . 2m, a combiner 16, an error correction component 17 for correcting for the B error of a shared signal processing channel 1, an error correction component 18 for correcting for the A error of shared signal processing channel 1, a first type 1 error estimation block 31 for estimating the errors C₀, C₁, . . . C_{M-1} of the M signal processing slices 2a, 2b, . . . 2m, a type 2 error estimation block 32 for estimating the B error of a shared signal processing channel 1, a second type 1 error estimation block 33 for estimating the A error of the shared signal processing channel 1, and a slice coefficient compensation block 45 for compensating the coefficients of the error correction components 15a, 15b, . . . 15m for the A error.

In the illustrated embodiment, the slice coefficient compensation block 45 extracts the error A component of the type 1 error estimates from the first set of type 1 error estimates and uses the extracted component to correct for any bias introduced by the presence of error A into the estimates of the errors C₀, C₁, . . . C_{M-1}.

Thus, the slice correction coefficients for the error correction components 15a, 15b, . . . 15m are adjusted by an estimate of the A error.

In the illustrated embodiment, the extraction of the error A component is based on the error A being common to all M slices and/or dependent on a quantity introduced into the signal path before the M slices. For instance, the error A component can depend or be correlated to dither, chopping, modulation scheme, and/or any other property of the system.

FIG. 2B is a schematic diagram of another embodiment of a calibration system 60 with mitigation of interference between alike calibrations.

The calibration system 60 of FIG. 2B is similar to the calibration system 50 of FIG. 2B, except that the slice coefficient compensation block 45′ of FIG. 2B provides an estimate of the A error to the second type 1 error estimation block 33′. Implementing the calibration system 60 in this manner can aid or speed up the estimation process of the calibration used to correct for error A.

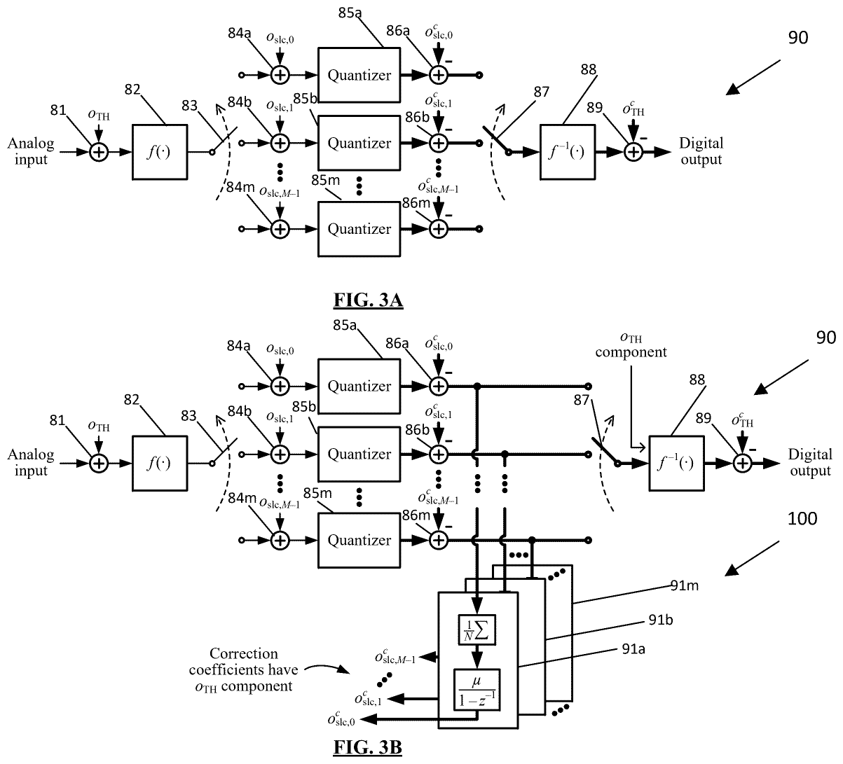

FIG. 3A is a schematic diagram of one example of a data converter system 90. The data converter system 90 includes a track and hold (TH) amplifier that introduces an offset, represented as adder 81 for an additive constant error source o_{TH}, and nonlinearity, represented by the f(·) nonlinear block 82. The data converter system 90 further includes an input switch 83 and an output switch 87 for selecting from M time-interleaved sub-ADCs or slices that include quantizers 85a, 85b, . . . 85m. The slices introduce an offset, represented by adders 84a, 84b, . . . 84m for additive constant error sources o_{slc,0}, o_{slc,1}, . . . , o_{slc,M-1}.

With continuing reference to FIG. 3A, the figure also shows where different corrections take place in the digital domain. The correction coefficients associated with the slices' offsets are labeled as o^{c}_{slc,0}, o^{c}_{slc,1}, . . . , o^{c}_{slc,M-1} (ideally, o^{c}_{slc,i}=o_{slc,i} for all i) and added to the output of each of the quantizers 85a, 85b, . . . 85m using adders 86a, 86b, . . . 86m, respectively. Additionally, the TH nonlinearity correction block 88 applies the inverse of f(·) to the slice-offset-corrected data. Furthermore, the correction coefficient associated with the TH offset is labeled as o^{c}_{TH} (ideally, o^{c}_{TH}=o_{TH}) and is added to the output of the TH nonlinearity correction block 88 using the adder 89.

FIG. 3B is a schematic diagram of one example of a calibration system 100 for the data converter system 90 of FIG. 3A.

The calibration system 100 includes averaging blocks 91a, 91b, . . . 91m for extracting an offset by averaging chunks of the digital signal of each slice with the offset present. This averaging generates an instantaneous offset error estimate, which can be used to update an accumulator with a forward gain of p (represented in FIG. 3B by a Z-transform of (1− [symbol] )⁻¹μ).

As the sensed offset decreases, the instantaneous offset error estimate also decreases, so the accumulator output's mean rate of change decreases as the calibration loop progresses. This process continues until, on average, the sensed offset error is zero, in which case the accumulator output is equal to a constant plus zero-mean error whose variance depends, among other things, on μ.

The constant value to which the accumulator output's mean converges corresponds to the value that causes the offset at the sensing point to be zero, so the slice offset correction coefficients converge to values that not only account for the targeted slice offsets, but also account for the TH offset that is present at that point in the signal path. This effect is shown by Equation 1 below.

$${o}_{slc , i}^{c} = {o}_{slc , i} + {o}_{TH} for i = 0 , 1 , … , M - 1 . \qquad Equation 1$$

The f⁻¹(·) correction block 88 is intended to take the slice-offset-corrected data and apply a nonlinear transformation to produce a digital representation of the analog signal at the input of the f(·) block 82. However, the spurious o_{TH} component in the slice offset correction coefficients introduces a DC component at the input of the f⁻¹(·) correction block 88, which causes this block 88 to introduce nonlinear distortion at the output of the ADC (in general, if a is a constant and x is any value, then f⁻¹(f(x)+a)≠x+a).

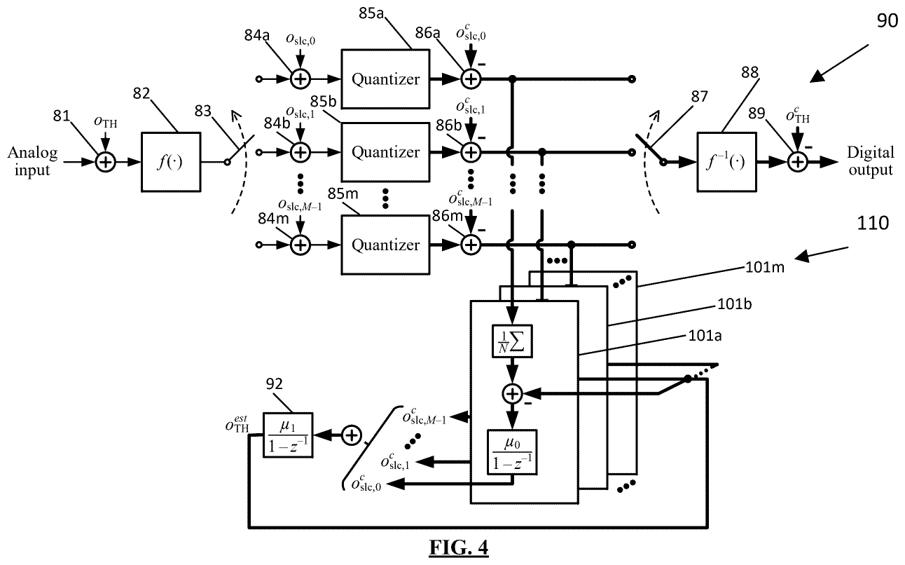

FIG. 4 is a schematic diagram of one embodiment of a calibration system 110 for the data converter system 90 of FIG. 3A.

The calibration system 110 includes averaging blocks 101a, 101b, . . . 101m for extracting an offset by averaging chunks of the digital signal of each slice with the offset present, and in which an estimate of the TH offset is subtracted from the inputs of accumulators with gain μ₀. The TH offset estimate is obtained from the average of the accumulators' outputs, which is used to drive another accumulator with gain μ₁ whose output corresponds to the estimate of the TH offset component.

Implementing the calibration system 110 in this manner mitigates the nonlinear error that would otherwise be introduced by the f⁻¹(·) correction block 88. For instance, such a technique can be particularly effective when the TH offset component is meaningfully larger than the mean of the slices' offsets.

Although the calibration system 100 of FIG. 4 uses averaging for extracting an error common to all slices, other types of computations can be performed to extract a common error. Thus, averaging is not the only resource that can be used for the purpose of extracting a common error, as there are other properties of the system that can be exploited depending on the impairments and the specifics of the calibrations under consideration.

Furthermore, chopping, dithering, dependence on previous samples (memory), and/or modulation can be exploited to orthogonally detect impairments originating from different parts of the system. Once the impairments are orthogonally detected, they can be corrected for in the right places to mitigate interference between calibrations and improve correction accuracy.

The calibration systems herein can be implemented in a wide variety of ways. In certain implementations, the calibration systems correspond to a computing system that includes memory hardware that operates in conjunction with data processing hardware to perform various calibration functions, such as error estimation and generation of correction coefficients.

Such memory hardware stores instructions that when executed by the data causes the data processing hardware to perform various operations. These instructions (also known as computer programs, software, software applications or code) can be implemented in a high-level procedural and/or object-oriented programming language, and/or in assembly/machine language.

The data processing hardware can include one or more central processing units (CPUs), configurable compute units (for example, field programmable gate arrays or FPGAs), digital signal processors (DSPs), neural processing units (NPUs), application specific integrated circuits (ASICs), and/or any other hardware processing components. The memory hardware stores information non-transitorily within the computing system. The memory hardware can include a computer-readable medium, a volatile memory unit(s), and/or non-volatile memory unit(s). The memory hardware can include physical devices used to store programs (e.g., sequences of instructions) or data (e.g., program state information) on a temporary or permanent basis for use by the computing system. Examples of non-volatile memory include, but are not limited to, flash memory and read-only memory (ROM)/programmable read-only memory (PROM)/erasable programmable read-only memory (EPROM)/electronically erasable programmable read-only memory (EEPROM) (e.g., typically used for firmware, such as boot programs). Examples of volatile memory include, but are not limited to, random access memory (RAM), dynamic random-access memory (DRAM), static random-access memory (SRAM), phase change memory (PCM) as well as disks or tapes.

### CONCLUSION

The foregoing description may refer to elements or features as being “connected” or “coupled” together. As used herein, unless expressly stated otherwise, “connected” means that one element/feature is directly or indirectly connected to another element/feature, and not necessarily mechanically. Likewise, unless expressly stated otherwise, “coupled” means that one element/feature is directly or indirectly coupled to another element/feature, and not necessarily mechanically. Thus, although the various schematics shown in the figures depict example arrangements of elements and components, additional intervening elements, devices, features, or components may be present in an actual embodiment (assuming that the functionality of the depicted circuits is not adversely affected).

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while the disclosed embodiments are presented in a given arrangement, alternative embodiments may perform similar functionalities with different components and/or circuit topologies, and some elements may be deleted, moved, added, subdivided, combined, and/or modified. Each of these elements may be implemented in a variety of different ways. Any suitable combination of the elements and acts of the various embodiments described above can be combined to provide further embodiments.

What is claimed is:

1. A signal processing system with mitigation of interference between alike calibrations, the signal processing system comprising:
a shared signal processing channel configured to process an input signal to generate an output signal, the shared signal processing channel having a first error of a first type;
a plurality of signal processing slices each configured to process the output signal from the shared signal processing channel, the plurality of signal processing slices having a plurality of errors of the first type; and
a calibration system configured to provide the plurality of signal processing slices with a plurality of slice correction coefficients that compensate the plurality of signal processing slices for the plurality of errors,
wherein the calibration system adjusts each of the plurality of slice correction coefficients based on an estimate of the first error.

2. The signal processing system of claim 1, wherein the calibration system generates estimates of the plurality of errors of the signal processing slices, and subtracts the estimate of the first error from the estimates to generate corrected estimates.

3. The signal processing system of claim 2, wherein the calibration system includes a plurality of first accumulators that receive the corrected estimates and generate the plurality of slice correction coefficients.

4. The signal processing system of claim 3, wherein the calibration system further includes a second accumulator that generates the estimate of the first error based on an average of the plurality of slice correction coefficients.

5. The signal processing system of claim 1, wherein the shared signal processing channel further has a second error of a second type.

6. The signal processing system of claim 5, wherein the first type of error is an offset and the second type of error is a nonlinearity.

7. The signal processing system of claim 1, wherein the first type of error is one of an offset, a gain error, a nonlinearity, a memory effect, or a capacitor mismatch.

8. The signal processing system of claim 1, wherein the shared signal processing channel includes an amplifier.

9. The signal processing system of claim 1, wherein the plurality of signal processing slices correspond to a plurality of analog-to-digital (ADC) data conversion channels of a pipelined ADC.

10. The signal processing system of claim 1, wherein the plurality of signal processing slices include a plurality of quantizers that generate a plurality of digital slice output signals, and a plurality of adders that add the plurality of slice correction coefficients with a corresponding one of the plurality of digital slice output signals to generate a plurality of corrected digital slice output signals.

11. The signal processing system of claim 10, wherein the calibration system generates estimates of the plurality of errors of the signal processing slices based on averaging the plurality of corrected digital slice output signals.

12. The signal processing system of claim 10, further comprising a combiner that combines the plurality of corrected digital slice output signals to generate a combined digital output signal at an output, wherein the calibration system further includes an error estimation block for the first error downstream from the output of the combiner.

13. The signal processing system of claim 12, wherein the calibration system provides the estimate of the first error to the error estimation block for the first error.

14. The signal processing system of claim 1, wherein the plurality of signal processing slices operate in parallel to process the output signal.

15. The signal processing system of claim 1, wherein the plurality of signal processing slices are time interleaved.

16. A method of calibrating a signal processing system, the method comprising:
processing an input signal to generate an output signal using a shared signal processing channel that has a first error of a first type;
processing the output signal from the shared signal processing channel using a plurality of signal processing slices that have a plurality of errors of the first type;
compensating the plurality of signal processing slices for the plurality of errors by providing the plurality of signal processing slices with a plurality of slice correction coefficients from a calibration system; and
adjusting each of the plurality of slice correction coefficients based on an estimate of the first error using the calibration system.

17. The method of claim 16, further comprising generating estimates of the plurality of errors of the signal processing slices, and subtracting the estimate of the first error from the estimates to generate corrected estimates.

18. The method of claim 17, wherein the calibration system includes a plurality of first accumulators that receive the corrected estimates and generate the plurality of slice correction coefficients.

19. The method of claim 18, wherein the calibration system further includes a second accumulator that generates the estimate of the first error based on an average of the plurality of slice correction coefficients.

20. The method of claim 16, wherein the shared signal processing channel further has a second error of a second type.
